(19) United States
(12) Patent Application Publication
(10) Pub. No.: US 2025/0081523 A1
(43) Pub. Date: Mar. 6, 2025

(54) CONTACTS IN SEMICONDUCTOR DEVICES AND METHODS OF FORMING THE SAME

(71) Applicant: Taiwan Semiconductor Manufacturing Co., Ltd., Hsinchu (TW)

(72) Inventors: Chen-Ming Lee, Yangmei City (TW); Shih-Chieh Wu, Hsinchu (TW); Po-Yu Huang, Hsinchu (TW); I-Wen Wu, Hsinchu (TW); Fu-Kai Yang, Hsinchu (TW); Mei-Yun Wang, Chu-Pei City (TW)

(21) Appl. No.: 18/239,283

(22) Filed: Aug. 29, 2023

(51) Int. Cl. H01L 29/417; H01L 21/8238; H01L 23/528; H01L 27/092; H01L 29/06; H01L 29/423; H01L 29/66; H01L 29/775; H01L 29/786

(52) U.S. Cl. CPC H10D 30/6729; H01L 23/5283; H10D 30/014; H10D 30/43; H10D 30/6735; H10D 30/6757; H10D 62/121; H10D 84/017; H10D 84/0186; H10D 84/038; H10D 84/85

(57) ABSTRACT

A semiconductor die and the method of forming the same are provided. The semiconductor die includes a first interconnect structure, a second interconnect structure including a conductive feature, and a device layer between the first interconnect structure and the second interconnect structure. The device layer includes a semiconductor fin, a first gate structure on the semiconductor fin, a source/drain region adjacent the first gate structure, and a shared contact extending through the semiconductor fin to be electrically connected to the source/drain region and the first gate structure. The conductive feature contacts the shared contact.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 11D, 12A, 12B, 12C, 12D, 12E, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, 22C, 23, 24, 25, 26, 27, 28, 29A, and 29B are views of intermediate stages in the manufacturing of a semiconductor die including nano-FETs, in accordance with some embodiments.

FIGS. 30A and 30B are views of a semiconductor die including nano-FETs, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor die with a front-side interconnect structure and a back-side interconnect structure on a front-side and a back-side of a device layer, respectively. Conductive contacts extend between and electrically connect the front-side interconnect structure and the front-side of the device layer as well as the back-side interconnect structure and the back-side of the device layer. Specifically, a shared contact connects a conductive line of the back-side interconnect structure to both a gate structure and a source/drain region at the back-side of the device layer. As a result, the density of the conductive contacts on the front-side of the device layer is reduced, which may reduce shorting and parasitic capacitance between adjacent conductive contacts on the front-side of the device layer, thereby improving the performance and the long-term reliability of the semiconductor die.

Some embodiments discussed herein are described in the context of a semiconductor die including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

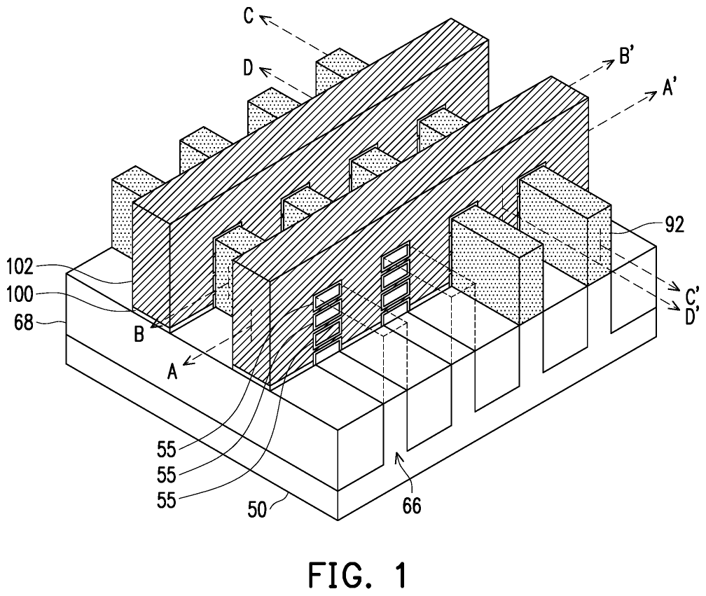

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A′ is along a longitudinal axis of a gate electrode 102 and in a direction, for example, perpendicular to the direction of current flow between the epitaxial source/drain regions 92 of a nano-FET. Reference cross-section B-B′ is parallel to reference cross-section A-A′ and extends through epitaxial source/drain regions 92 of multiple nano-FETs. Reference cross-section C-C′ is perpendicular to reference cross-section A-A′ and is parallel to a longitudinal axis of a fin 66 of the nano-FET and in a direction of, for example, a current flow between the epitaxial source/drain regions 92 of the nano-FET. Reference cross-section D-D′ is parallel to reference cross-section C-C′ and extends through gate electrodes 102 of multiple nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

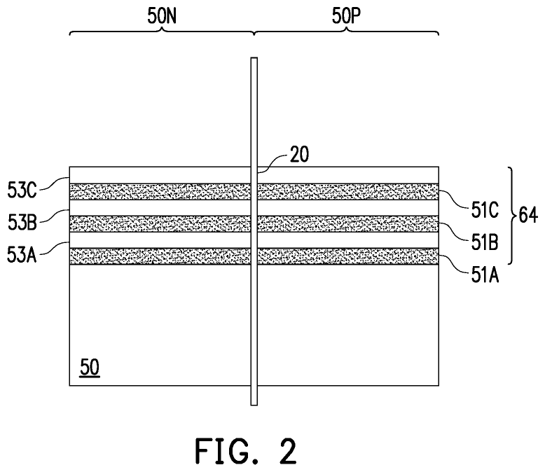

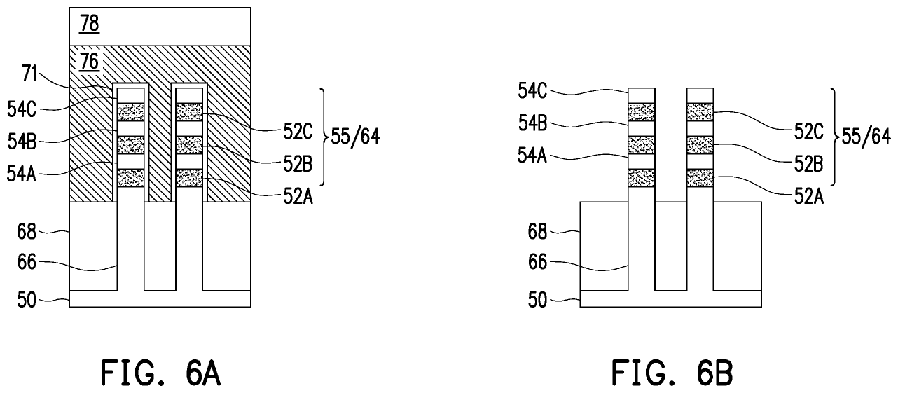

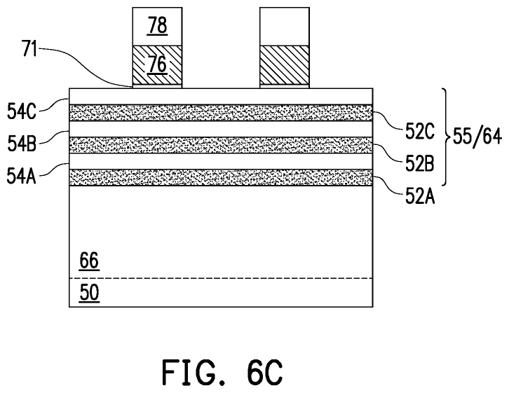

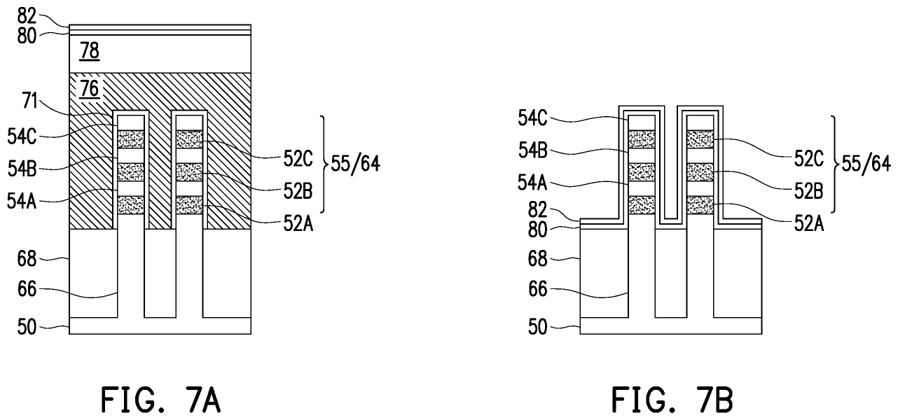

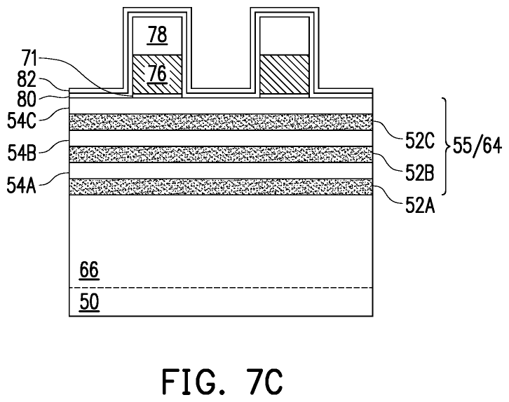

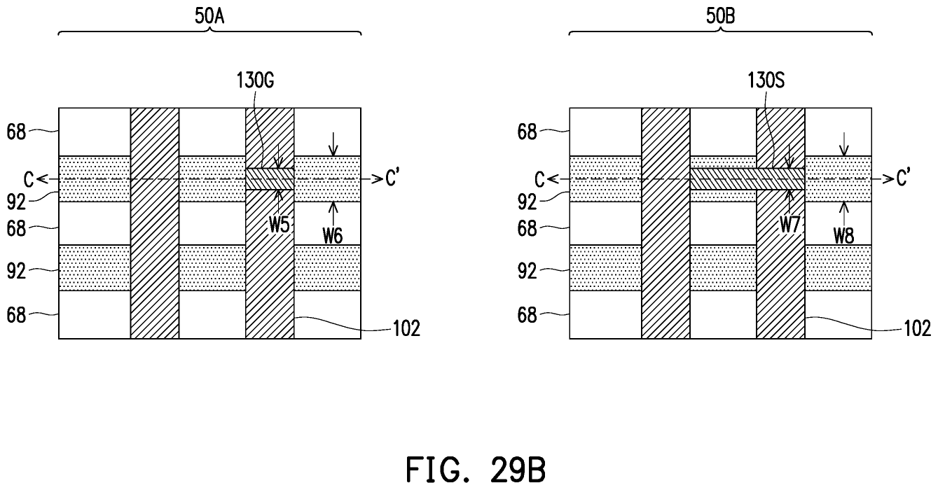

FIGS. 2 through 28C are views of intermediate stages in the manufacturing of a semiconductor die including nano-FETs, in accordance with some embodiments. FIGS. 2, 3, 4, 5, 6A, 7A, 8A, 9A, 10A, 11A, 12A, 13A, 14A, 15A, 16A, 17A, 18A, 19A, 20A, 21A, and 22A illustrate cross-sectional views along reference cross-section A-A′ illustrated in FIG. 1. FIGS. 6B, 7B, 8B, 9B, 10B, 11B, 12B, 12D, 13B, 14B, 15B, 16B, 17B, 18B, 19B, 20B, 21B, and 22B illustrate cross-sectional views along reference cross-section B-B′ illustrated in FIG. 1. FIGS. 7C, 8C, 9C, 10C, 11C, 11D, 12C, 12E, 13C, 14C, 15C, 16C, 17C, 18C, 19C, 20C, 21C, 22C, 23, 24, 25, 26, 27, 28, and 29A illustrate cross-sectional views along reference cross-section C-C′ illustrated in FIG. 1. FIG. 29B is a top-down view, where the regions of FIG. 29A are shown along reference cross-sections C-C′ in FIG. 29B.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon, carbon-doped silicon, or the like.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

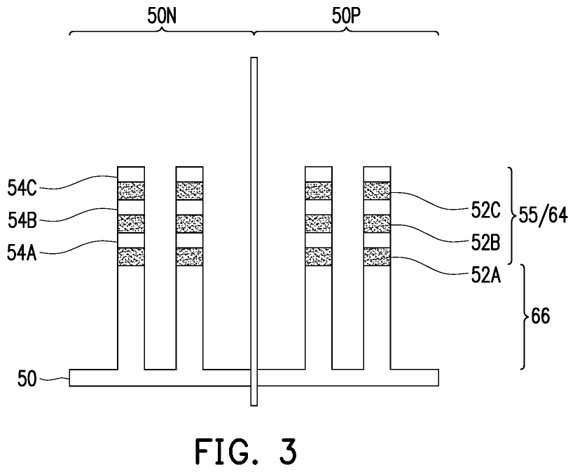

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

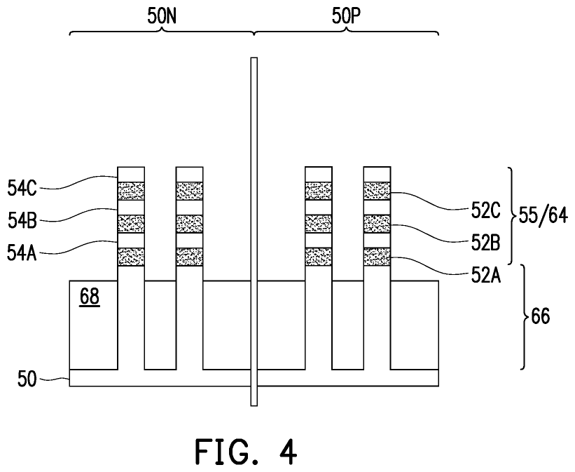

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

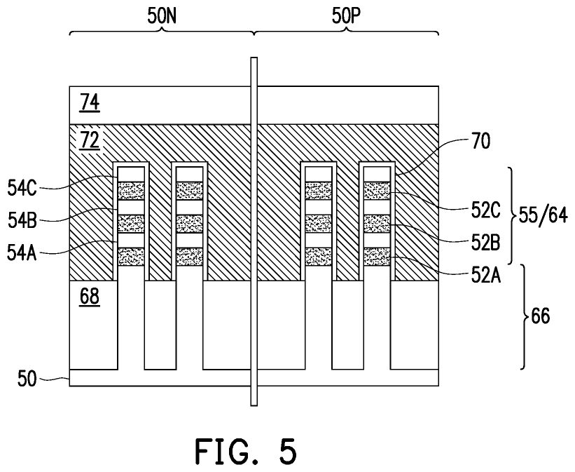

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 18C illustrate various additional steps in the manufacturing of embodiment nano-FET devices. FIGS. 6A through 18C illustrate features in either the n-type region 50N or the p-type region 50P. In FIGS. 6A through 6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A through 7C, a first spacer layer 80 and a second spacer layer 82 are formed over the structures illustrated in FIGS. 6A through 6C. The first spacer layer 80 and the second spacer layer 82 will be subsequently patterned to act as spacers for forming self-aligned source/drain regions. In FIGS. 7A through 7C, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An annealing may be used to repair implant damage and to activate the implanted impurities.

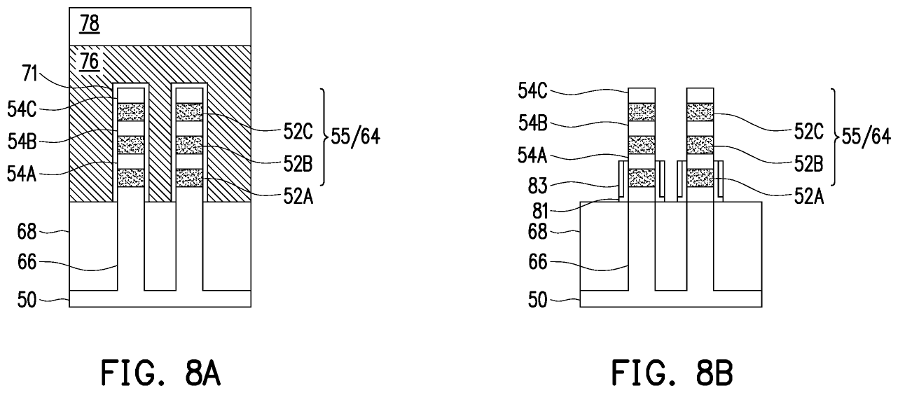

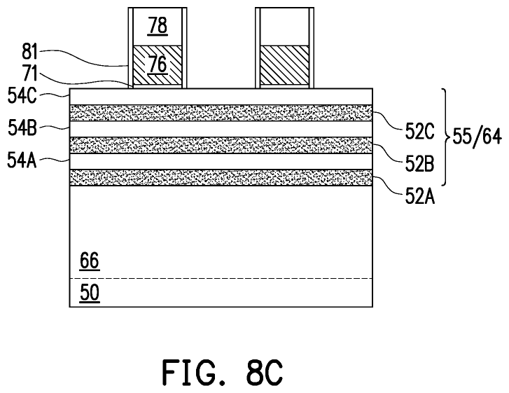

In FIGS. 8A through 8C, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8B. Thereafter, the second spacers 83 acts as a mask while etching exposed portions of the first spacer layer 80, thereby forming first spacers 81 as illustrated in FIGS. 8B and 8C.

As illustrated in FIG. 8B, the first spacers 81 and the second spacers 83 are disposed on sidewalls of the fins 66 and/or nanostructures 55. As illustrated in FIG. 8C, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 71. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

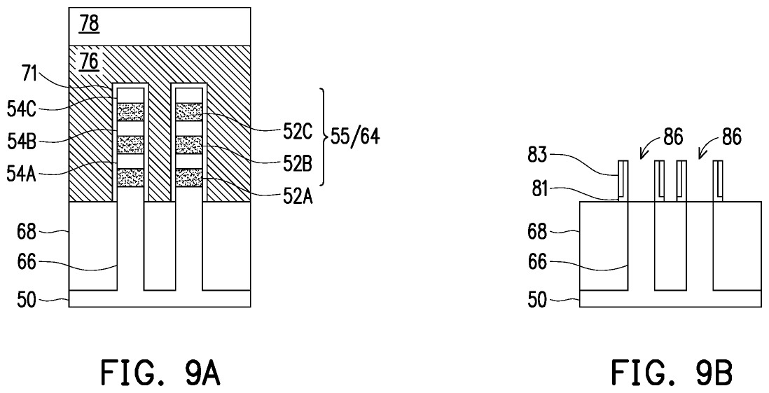

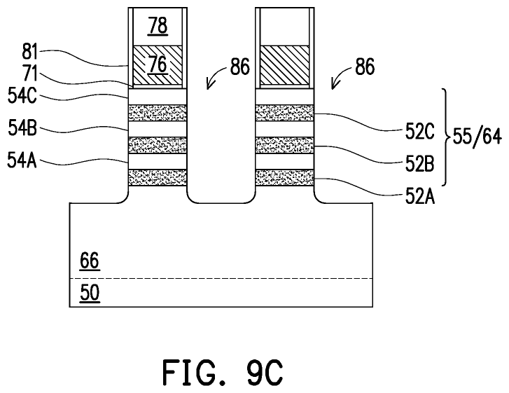

In FIGS. 9A through 9C, recesses 86 are formed in the fins 66, the nanostructures 55, and the substrate 50, in accordance with some embodiments. Epitaxial source/drain regions will be subsequently formed in the recesses 86. The recesses 86 may extend through the first nanostructures 52 and the second nanostructures 54, and into the substrate 50. As illustrated in FIG. 9B, top surfaces of the STI regions 68 may be level with bottom surfaces of the recesses 86. In various embodiments, the fins 66 may be etched such that bottom surfaces of the recesses 86 are disposed below the top surfaces of the STI regions 68 or the like. The recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the recesses 86. A single etch process or multiple etch processes may be used to etch each layer of the nanostructures 55 and/or the fins 66. Timed etch processes may be used to stop the etching after the recesses 86 reach desired depths.

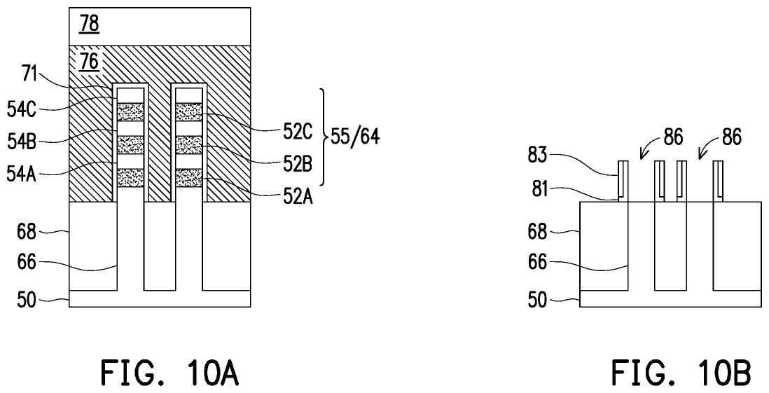

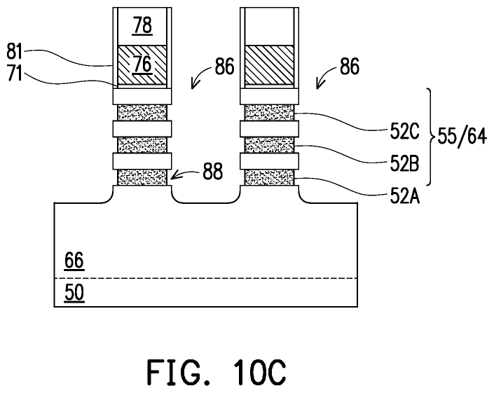

In FIGS. 10A through 10C, portions of sidewalls of the layers of the multi-layer stack 64 formed of the first semiconductor materials (e.g., the first nanostructures 52) exposed by the recesses 86 are etched to form sidewall recesses 88. Although sidewalls of the first nanostructures 52 adjacent the sidewall recesses 88 are illustrated as being straight in FIG. 10C, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

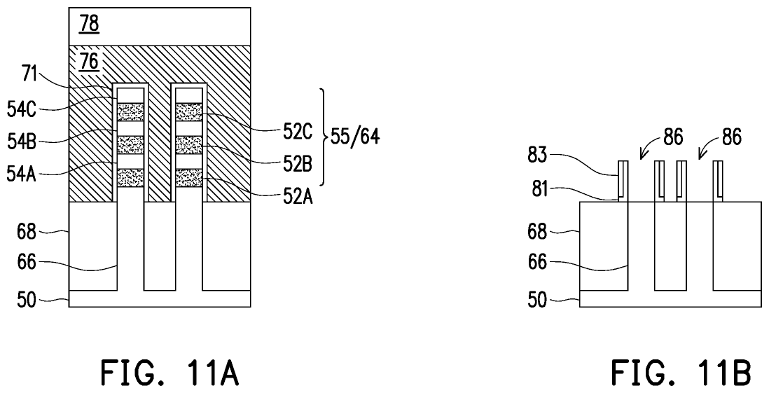

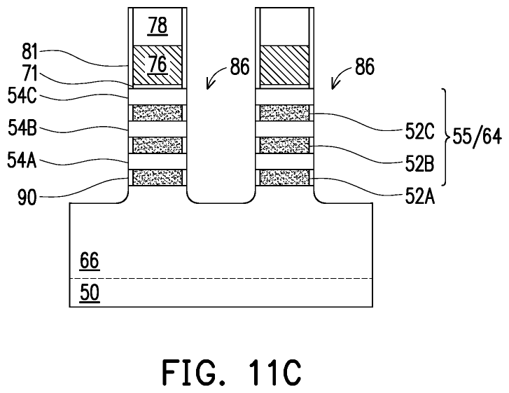

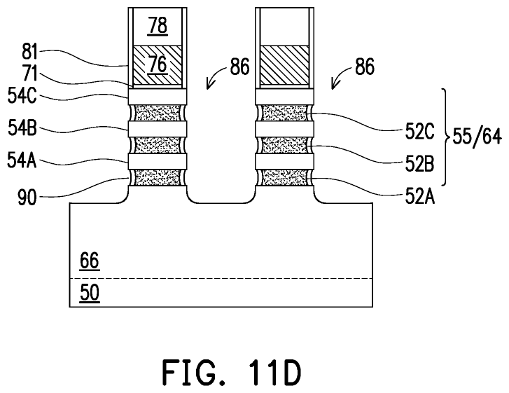

In FIGS. 11A through 11D, first inner spacers 90 are formed in the sidewall recess 88. The first inner spacers 90 may be formed by depositing an inner spacer layer (not separately illustrated) over the structures illustrated in FIGS. 10A through 10C. The first inner spacers 90 act as isolation features between subsequently formed source/drain regions and a gate structure. As will be discussed in greater detail below, source/drain regions and epitaxial materials will be formed in the recesses 86, while the first nanostructures 52 will be replaced with corresponding gate structures. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54.

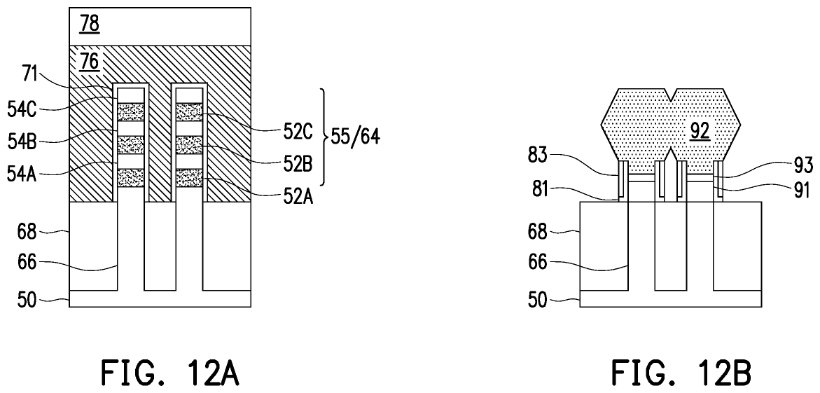

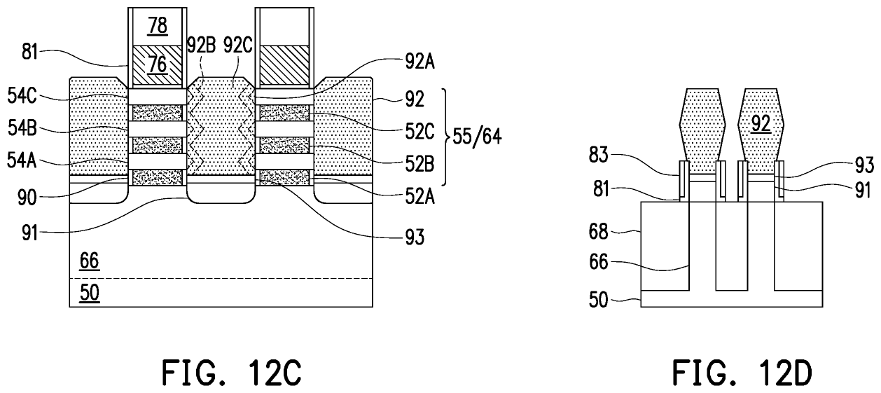

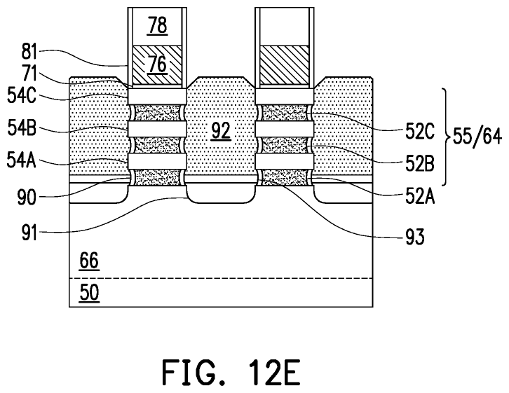

Moreover, although the outer sidewalls of the first inner spacers 90 are illustrated as being straight in FIG. 11C, the outer sidewalls of the first inner spacers 90 may be concave or convex. As an example, FIG. 11D illustrates an embodiment in which sidewalls of the first nanostructures 52 are concave, outer sidewalls of the first inner spacers 90 are concave, and the first inner spacers 90 are recessed from sidewalls of the second nanostructures 54. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A through 12E) by subsequent etching processes, such as etching processes used to form gate structures.

In FIGS. 12A through 12E, semiconductor layers 91, bottom spacers 93, and epitaxial source/drain regions 92 are formed in the recesses 86. The semiconductor layers 91 may be formed on the fins 66. The semiconductor layers 91 may be in contact with the sidewalls of the first inner spacers 90 on the first nanostructures 52A. Bottom surfaces of the semiconductor layers 91 may be disposed below bottom surfaces of the first inner spacers 90 on the first nanostructures 52A. Top surfaces of the semiconductor layers 91 may be disposed below top surfaces of the first inner spacers 90 on the first nanostructures 52A. Thus, the semiconductor layers 91 may not be on the sidewalls of the second nanostructures 54. The semiconductor layers 91 may be formed of a semiconductor material selected from the candidate semiconductor materials of the substrate 50, which may be grown by an epitaxial growth process such as VPE, MBE, or the like. Timed epitaxial growth processes may be used to grow the semiconductor layers 91 to certain heights.

The bottom spacers 93 are formed on the semiconductor layers 91. The bottom spacers 93 may be in contact with the first inner spacers 90 on the first nanostructures 52A. Bottom surfaces of the bottom spacers 93 may be disposed above the bottom surfaces of the first inner spacers 90 on the first nanostructures 52A. Top surfaces of the bottom spacers 93 may be disposed below the top surfaces of the first inner spacers 90 on the first nanostructures 52A. Thus, the bottom spacers 93 may not be on the sidewalls of the second nanostructures 54. The bottom spacers 93 may be formed by conformally forming one or more dielectric material(s) over the semiconductor layers 91 and subsequently etching back the dielectric material(s). Acceptable dielectric materials may include silicon nitride, silicon oxynitride, silicon oxycarbonitride, silicon oxycarbide, silicon carbonitride, silicon oxide, aluminum oxide, hafnium oxide, or the like, which may be formed by a deposition process, such as CVD, ALD, or the like. Any acceptable etch process, such as a dry etch, a wet etch, the like, or a combination thereof, may be performed to pattern the dielectric material(s).

The epitaxial source/drain regions 92 are then formed in the recesses 86 and on the bottom spacers 93. In some embodiments, the epitaxial source/drain regions 92 may exert stress on the second nanostructures 54, thereby improving performance. As illustrated in FIG. 12C, the epitaxial source/drain regions 92 are formed in the recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 64 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12B. In other embodiments, adjacent epitaxial source/drain regions 92 remain separated after the epitaxy process is completed as illustrated by FIG. 12D. In the embodiments illustrated in FIGS. 12B and 12D, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 12C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

FIG. 12E illustrates an embodiment in which sidewalls of the first nanostructures 52 are concave, outer sidewalls of the first inner spacers 90 are concave, and the first inner spacers 90 are recessed from sidewalls of the second nanostructures 54. As illustrated in FIG. 12E, the epitaxial source/drain regions 92 may be formed in contact with the first inner spacers 90 and may extend past sidewalls of the second nanostructures 54.

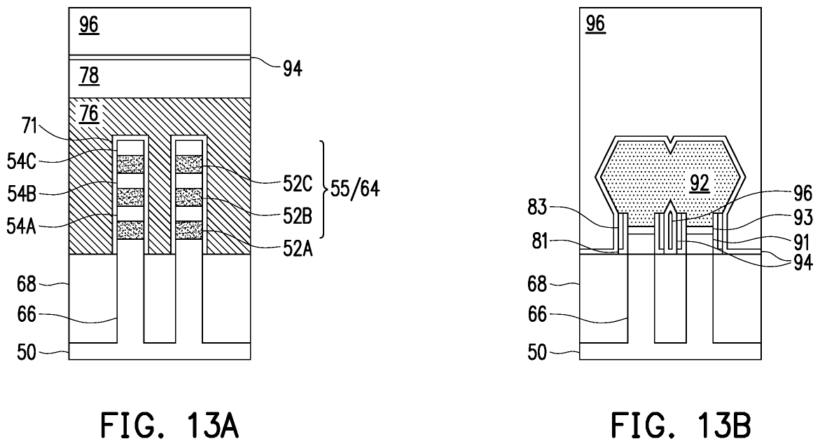

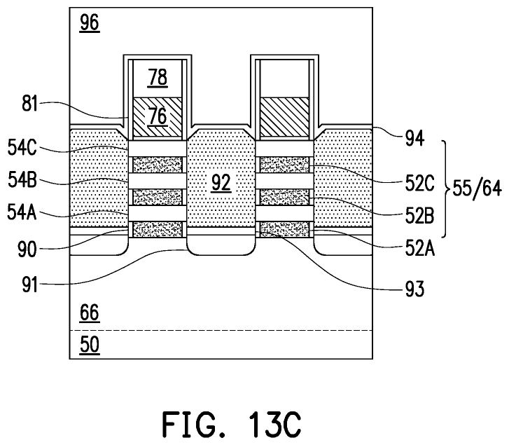

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

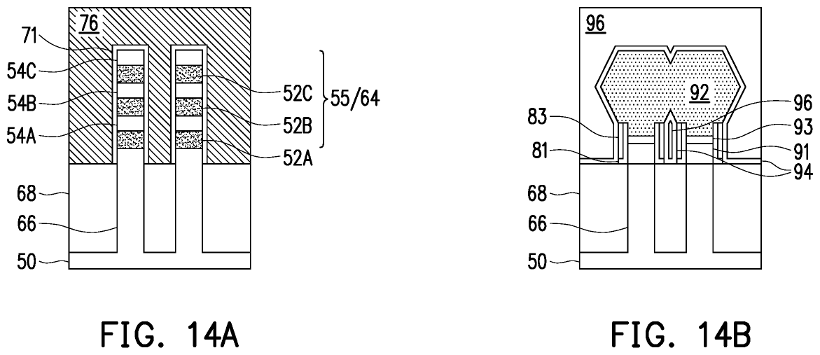

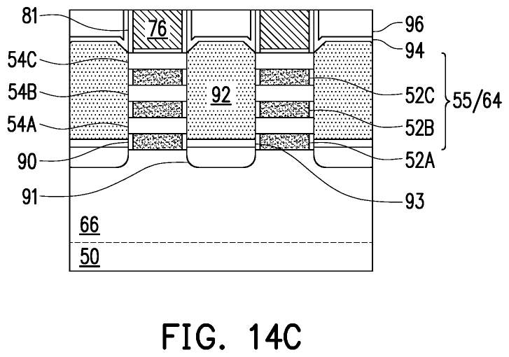

In FIGS. 14A through 14C, a planarization process, such as CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

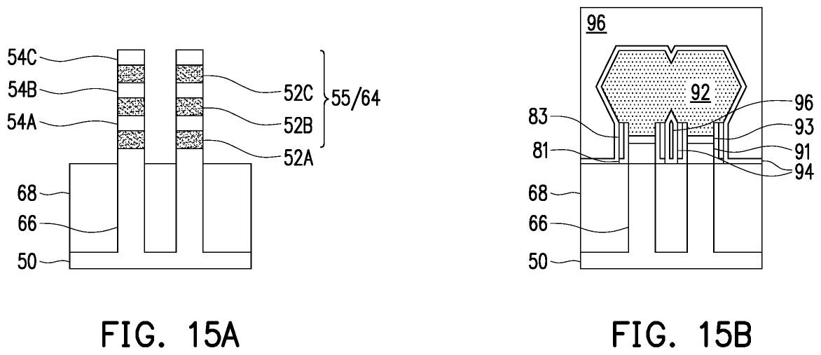

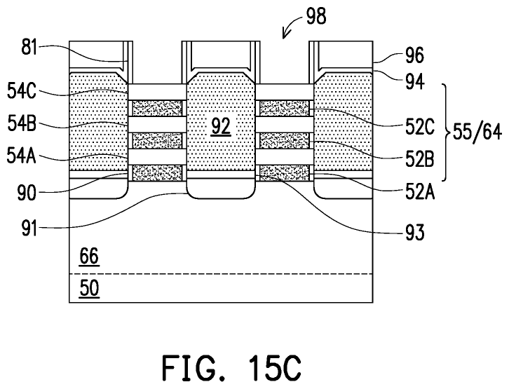

In FIGS. 15A through 15C, the dummy gates 76, and the masks 78 if present, are removed in one or more etching steps, so that third recesses 98 are formed. Portions of the dummy gate dielectrics 71 in the third recesses 98 are also be removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 96 or the first spacers 81. Each of the third recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

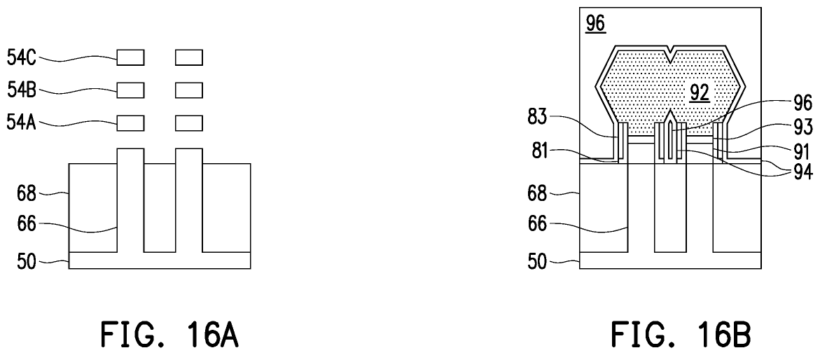

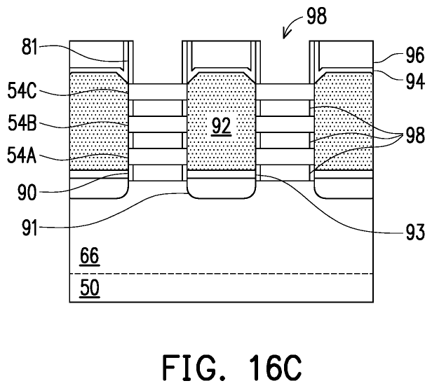

In FIGS. 16A through 16C, the first nanostructures 52 are removed extending the third recesses 98. The first nanostructures 52 may be removed by performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52.

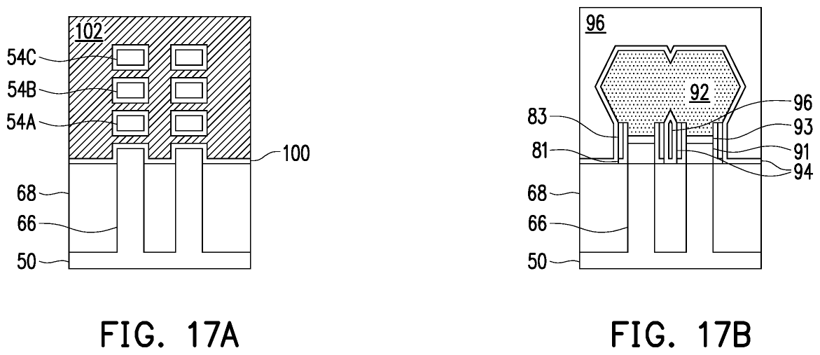

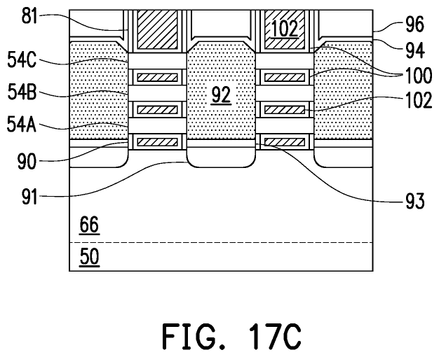

In FIGS. 17A through 17C, gate dielectric layers 100 and gate electrodes 102 are formed for replacement gates. The gate dielectric layers 100 are deposited conformally in the third recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the first spacers 81, and the STI regions 68 and on sidewalls of the first spacers 81 and the first inner spacers 90.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the third recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

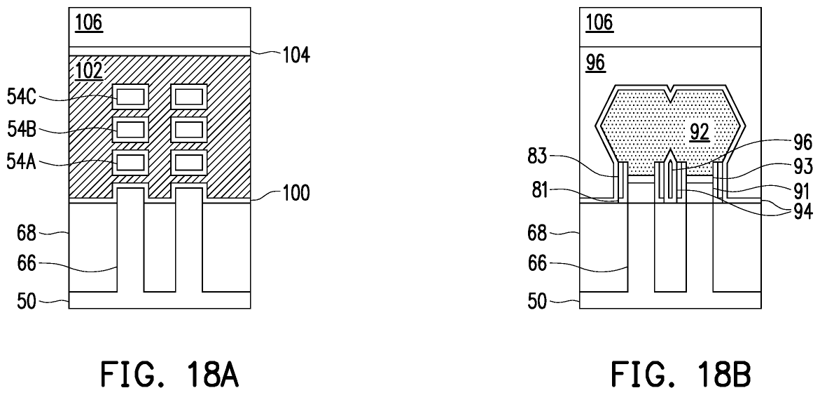

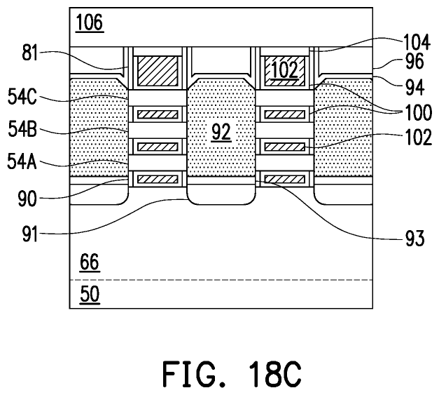

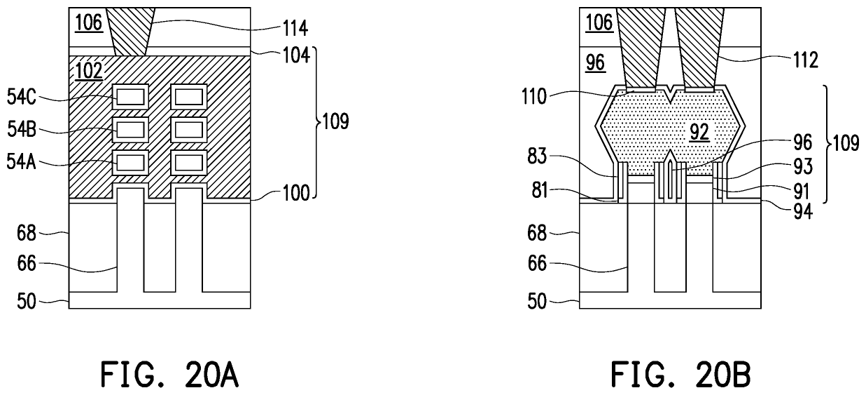

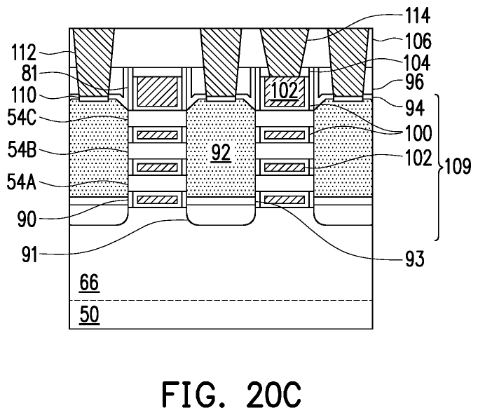

In FIGS. 18A through 18C, the gate structures (including the gate dielectric layers 100 and the corresponding overlying gate electrodes 102) are recessed, so that recess are formed directly over the gate structures and between opposing portions of first spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts (such as the gate contacts 114, discussed below with respect to FIGS. 20A through 20C) penetrate through the gate masks 104 to contact the top surfaces of the recessed gate electrodes 102.

As further illustrated by FIGS. 18A through 18C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

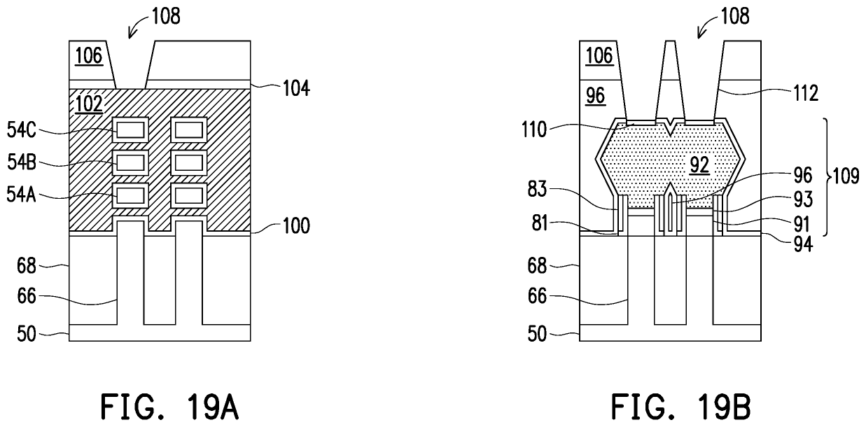

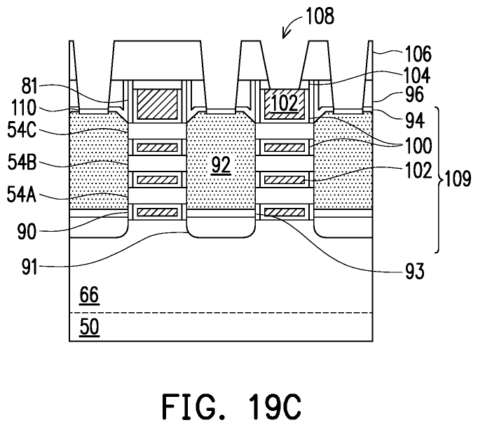

In FIGS. 19A through 19C, the second ILD 106, the first ILD 96, the CESL 94, and the gate masks 104 are etched to form fourth recesses 108 exposing surfaces of the epitaxial source/drain regions 92 and/or some of the gate structures. Some of the gate structures may not be exposed by the fourth recesses 108. Desired one of the gate structures (e.g., ones that are not exposed by the fourth recesses 108) may be connected to conductive contacts that extend through the substrate 50, which may be subsequently formed as described in greater detail below. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures. Although FIG. 19C illustrates the fourth recesses 108 as exposing the epitaxial source/drain regions 92 and some of the gate structures in a same cross-section, in various embodiments, the epitaxial source/drain regions 92 and some of the gate structures may be exposed in different cross-sections, thereby reducing the risk of shorting subsequently formed contacts.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a first thermal annealing process to form the first silicide regions 110. In some embodiments, the first thermal annealing process is performed at a temperate of about 450° C. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

In FIGS. 20A through 20C, source/drain contacts 112 and gate contacts 114, which may be also referred to as conductive contacts, are formed in the fourth recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106.

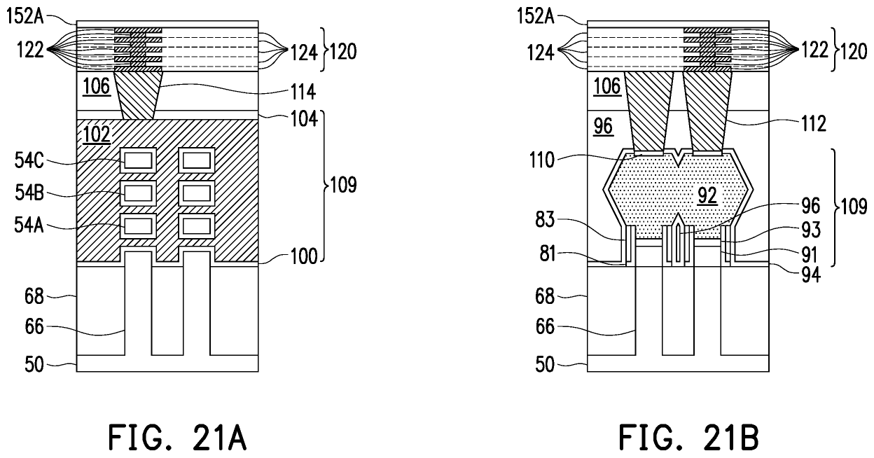

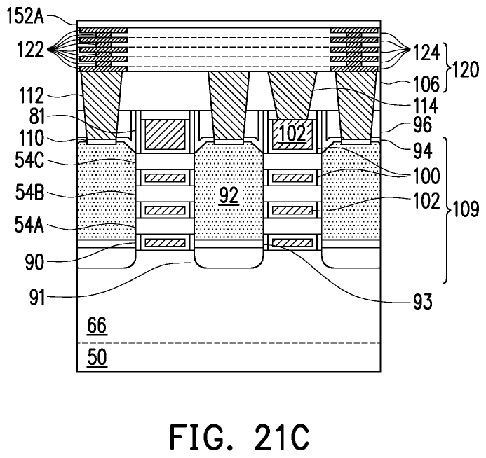

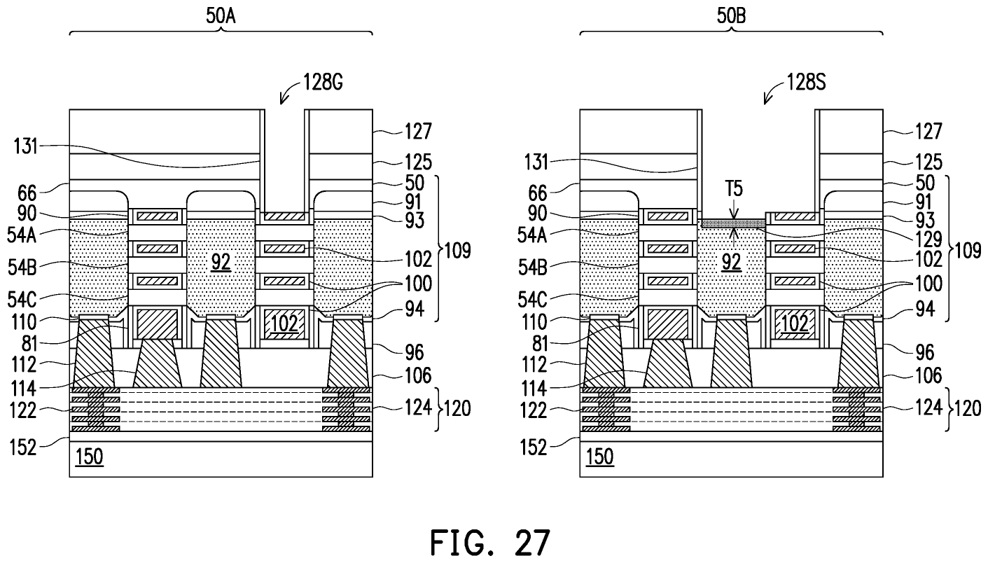

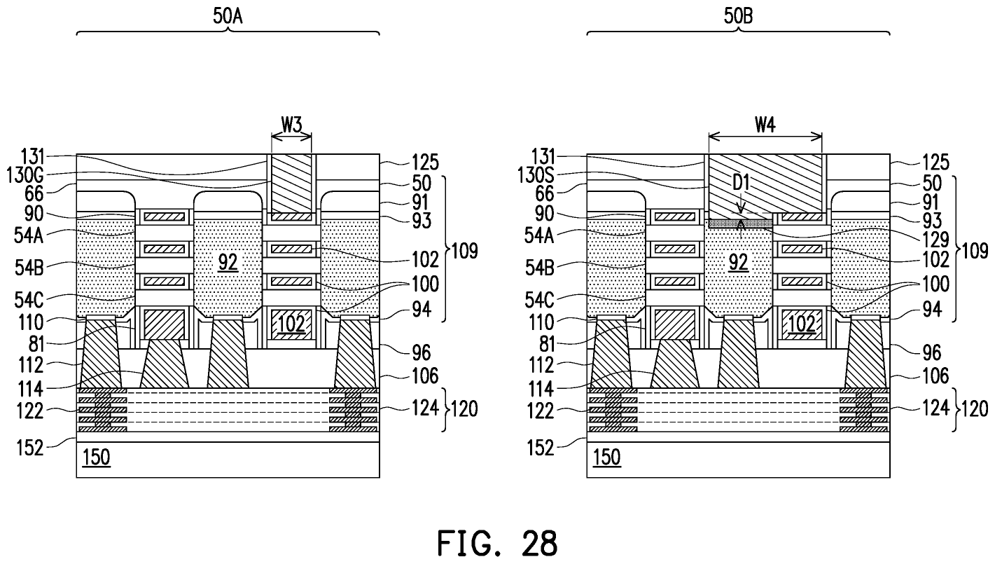

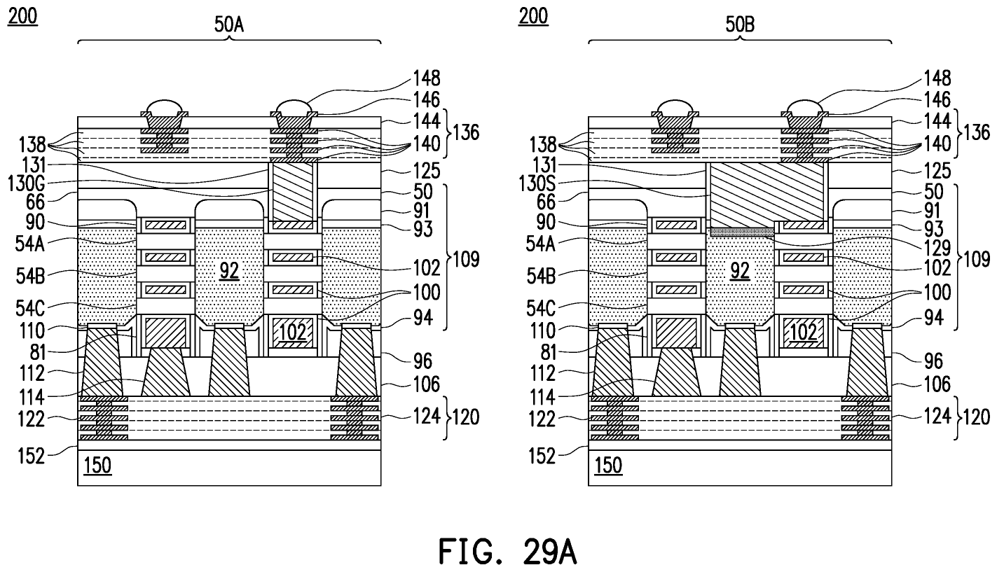

The epitaxial source/drain regions 92, the second nanostructures 54 (e.g., channel regions), and the gate structures (including the gate dielectric layers 100 and the gate electrodes 102) may collectively be referred to as transistor structures 109. The transistor structures 109 may be collectively disposed in a device layer, with a first interconnect structure (such as the front-side interconnect structure 120, discussed below with respect to FIGS. 21A through 21C) being formed over a front-side of the device layer, and a second interconnect structure (such as the back-side interconnect structure 136, discussed below with respect to FIGS. 27A through 28C) being formed over a back-side of the device layer. Although the device layer is described as having nano-FETs, other embodiments may include a device layer having different types of transistors (e.g., planar FETs, finFETs, thin film transistors (TFTs), or the like).

FIGS. 20A through 20C illustrate some of the gate structures not being connected to the gate contacts 114. As described in greater detail below, some gate structures (e.g., the gate structures that are not connected to the conductive contacts on the front-sides of the transistor structures 109) may be connected to conductive contacts that will be subsequently formed on the back-sides of the transistor structures 109. As a result, the density of the conductive contacts, including the source/drain contacts 112 and the gate contacts 114, on the front-sides of the transistor structures 109 may be reduced, which may reduce shorting and parasitic capacitance between adjacent conductive contacts on the front-sides of the transistor structures 109, thereby improving the performance and the long-term reliability of the semiconductor die.

FIGS. 20A through 20C illustrate a source/drain contact 112 extending to each of the epitaxial source/drain regions 92 on the front-sides of the transistor structures 109 as an example. In some embodiments, as described in greater detail below, conductive contacts may be subsequently formed on the back-sides of the transistor structures 109 to be electrically connected to the back-sides of some of the epitaxial source/drain regions 92. For such epitaxial source/drain regions 92, the source/drain contacts 112 at the front-sides of the epitaxial source/drain regions 92 may be omitted.

FIGS. 21A through 29B illustrate intermediate stages of forming front-side interconnect structures and back-side interconnect structures on the transistor structures 109. The front-side interconnect structures and the back-side interconnect structures may each comprise conductive features that are electrically connected to the nano-FETs formed on the substrate 50 to provide functional circuits. The processes described in FIGS. 21A through 29B may be applied to both the n-type region 50N and the p-type region 50P.

In FIGS. 21A through 21C, a front-side interconnect structure 120 is formed on the second ILD 106. The front-side interconnect structure 120 may be referred to as a front-side interconnect structure because it is formed on the front-sides of the transistor structures 109 (e.g., a side of the transistor structures 109 on which active devices are formed). The front-side interconnect structure 120 may comprise one or more layers of first conductive features 122 formed in one or more stacked first dielectric layers 124. Each of the stacked first dielectric layers 124 may comprise a dielectric material, such as a low-k dielectric material, an extra low-k (ELK) dielectric material, or the like. The first dielectric layers 124 may be deposited using an appropriate process, such as, CVD, ALD, PVD, PECVD, or the like. The first conductive features 122 may comprise conductive lines and conductive vias interconnecting the layers of conductive lines. The conductive vias may extend through respective ones of the first dielectric layers 124 to provide vertical connections between layers of the conductive lines. A first layer of the conductive lines may be in contact with the source/drain contacts 112 and the gate contacts 114. The first conductive features 122 may be formed through any acceptable process, such as, a damascene process, a dual damascene process, or the like.

In some embodiments, the first conductive features 122 may be formed using a damascene process in which a respective first dielectric layer 124 is patterned utilizing a combination of photolithography and etching techniques to form trenches corresponding to the desired pattern of the first conductive features 122. An optional diffusion barrier and/or optional adhesion layer may be deposited, and the trenches may then be filled with a conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, combinations thereof, or the like. In an embodiment, the first conductive features 122 may be formed by depositing a seed layer of copper or a copper alloy, and filling the trenches by electroplating. A chemical mechanical planarization (CMP) process or the like may be used to remove excess conductive material from a surface of the respective first dielectric layer 124 and to planarize surfaces of the first dielectric layer 124 and the first conductive features 122 for subsequent processing.

FIGS. 21A through 21C illustrate five layers of the first conductive features 122 and the first dielectric layers 124 in the front-side interconnect structure 120. However, it should be appreciated that the front-side interconnect structure 120 may comprise any number of first conductive features 122 disposed in any number of first dielectric layers 124. The front-side interconnect structure 120 may be electrically connected to the gate contacts 114 and the source/drain contacts 112 to form functional circuits. In some embodiments, the functional circuits formed by the front-side interconnect structure 120 may comprise logic circuits, memory circuits, image sensor circuits, or the like.

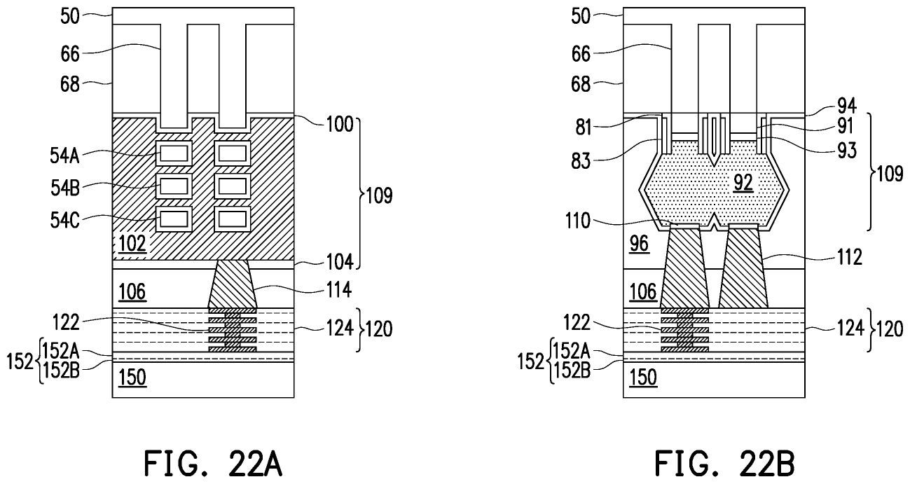

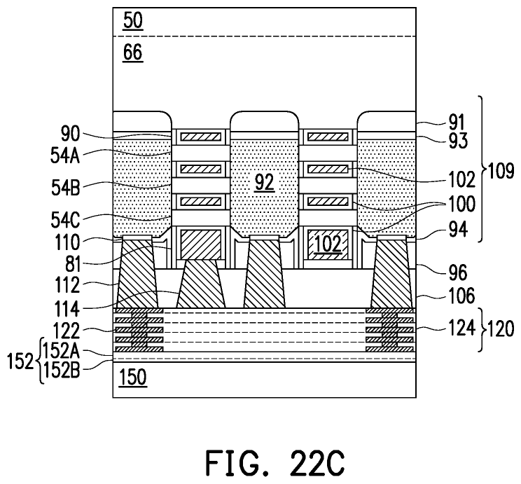

As also illustrated in FIGS. 21A through 21C, a first bonding layer 152A may be deposited over the front-side interconnect structure 120. The first bonding layer 152A may be deposited by any suitable process, such as PVD, CVD, ALD, or the like, and the first bonding layer 152A may facilitate the bonding of a carrier substrate in subsequent processes (see FIGS. 22A through 22C). The first bonding layer 152A may comprise an insulating material that is suitable for a subsequent dielectric-to-dielectric bonding process. Example materials for the first bonding layer 152A include silicon oxide (e.g., SiO₂), silicon nitride, silicon oxynitride, silicon carbonitride, silicon oxycarbonitride, or the like. Then a planarization process, such as CMP or the like, may be used to remove excess material from a surface of the first bonding layer 152A and to planarize the surface of the first bonding layer 152A for subsequent processing.

In FIGS. 22A through 22C, a carrier substrate 150 is bonded to a top surface of the front-side interconnect structure 120 by the first bonding layer 152A and a second bonding layer 152B. After bonding, the first bonding layer 152A and the second bonding layer 152B may be collectively referred to as a bonding layer 152. It should be appreciated that the bonding layer 152 may include an internal interface where the first bonding layer 152A and the second bonding layer 152B meet. The carrier substrate 150 may be a glass carrier substrate, a ceramic carrier substrate, a wafer (e.g., a silicon wafer), or the like. The carrier substrate 150 may provide structural support during subsequent processing steps and in the completed device. The second bonding layer 152B may be deposited on the carrier substrate 150 by any suitable process, such as PVD, CVD, ALD, or the like. The second bonding layer 152B may comprise an insulating material that is suitable for a dielectric-to-dielectric bonding process. Example materials for the second bonding layer 152B include silicon oxide (e.g., SiO₂), silicon nitride, silicon oxynitride, silicon carbonitride, silicon oxycarbonitride, or the like. The second bonding layer 152B may have a same or different thickness than the first bonding layer 152A.

After the second bonding layer 152B is deposited on the carrier substrate 150, the carrier substrate 150 may be bonded to the front-side interconnect structure 120 using a suitable technique, such as dielectric-to-dielectric bonding, or the like. The dielectric-to-dielectric bonding process may include applying a surface treatment to one or more of the first bonding layer 152A and the second bonding layer 152B. The surface treatment may include a plasma treatment. The plasma treatment may be performed in a vacuum environment. After the plasma treatment, the surface treatment may further include a cleaning process (e.g., a rinse with deionized water or the like) that may be applied to one or more of the bonding layers 152. The carrier substrate 150 is then aligned with the front-side interconnect structure 120 and the two are pressed against each other to initiate a pre-bonding of the carrier substrate 150 to the front-side interconnect structure 120. The pre-bonding may be performed at room temperature (e.g., between about 21° C. and about 25° C.). After the pre-bonding, an annealing process may be applied by, for example, heating the front-side interconnect structure 120 and the carrier substrate 150 to a temperature of in a range of 150° C. to 500° C. The annealing process drives the formation of covalent bonds between the first bonding layer 152A and the second bonding layer 152B. Other bonding processes, such as ambient bonding, vacuum bonding, or the like may be used in other embodiments.

Further in FIGS. 22A through 22C, after the carrier substrate 150 is bonded to the front-side interconnect structure 120, the device may be flipped such that a back-side of the transistor structures 109 faces upwards. The back-side of the transistor structures 109 may refer to a side opposite to the front-sides of the transistor structures 109 on which the active devices are formed.

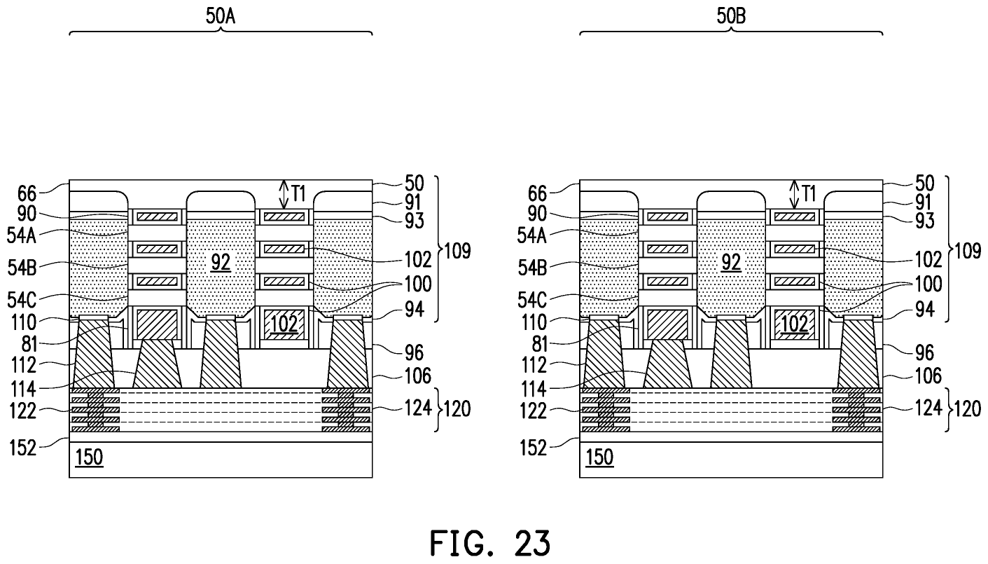

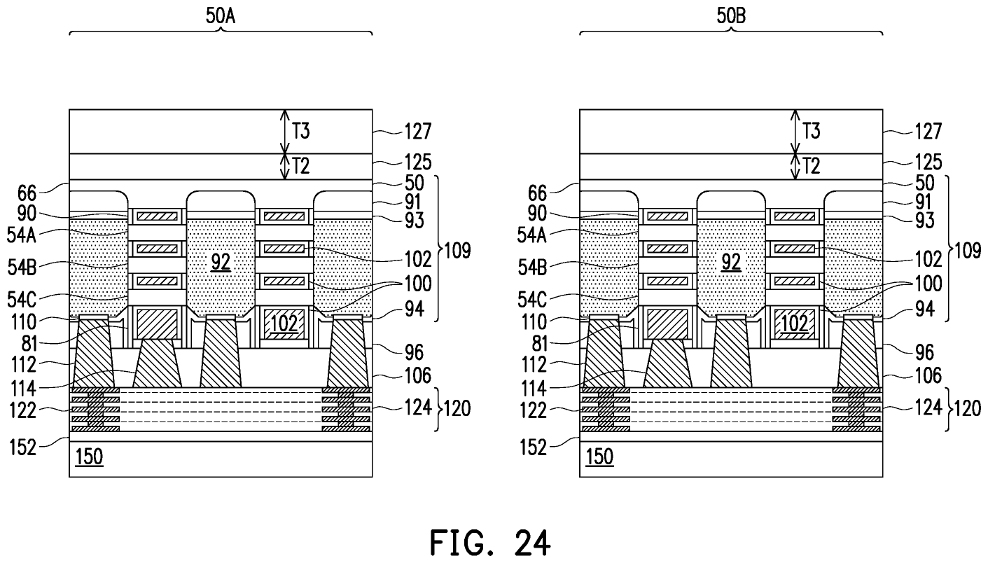

FIGS. 23 through 29B illustrate additional steps in the manufacturing of the semiconductor die. A region 50A and a region 50B of the semiconductor die are illustrated. The region 50A and the region 50B may be along a same fin 66 or along different fins 66. The region 50A and the region 50B may be across a same gate electrode 102 or across different gate electrodes 102.

In FIG. 23, a thinning process may be applied to the back-side of the substrate 50 in the region 50A and the region 50B. The thinning process may comprise a planarization process (e.g., a mechanical grinding, a CMP, or the like), an etch-back process, a combination thereof, or the like. Further, a portion of the substrate 50 may remain over the gate structures (e.g., the gate electrodes 102 and the gate dielectric layers 100), the semiconductor layers 91, and the bottom spacers 93. After the thinning process, the substrate 50 may have a thickness T1, which may be a distance between a surface of the gate structure (e.g., the gate electrodes 102 and the gate dielectric layers 100) and a back-side surface of the substrate 50. The thickness T1 may be in a range of about 5 nm to about 50 nm.

In I FIG. 24, a first back-side dielectric layer 125 is formed on the back-side surface of the substrate 50 in the region 50A and the region 50B, and a second back-side dielectric layer 127 is formed on first back-side dielectric layer 125 in the region 50A and the region 50B. The first back-side dielectric layer 125 and the second back-side dielectric layer 127 may be used as hard masks in a subsequent etching process, and may be formed of different materials. The first back-side dielectric layer 125 may be formed of a first dielectric material (e.g., silicon nitride or the like) and the second back-side dielectric layer 127 may be formed of a second dielectric material (e.g., silicon oxide or the like). The first back-side dielectric layer 125 and the second back-side dielectric layer 127 may be formed by multiple deposition processes, such as CVD, ALD, or the like. The first back-side dielectric layer 125 may have thickness T2 in a range of about 5 nm to about 15 nm. The second back-side dielectric layer 127 may have thickness T3 in a range of about 15 nm to about 45 nm.

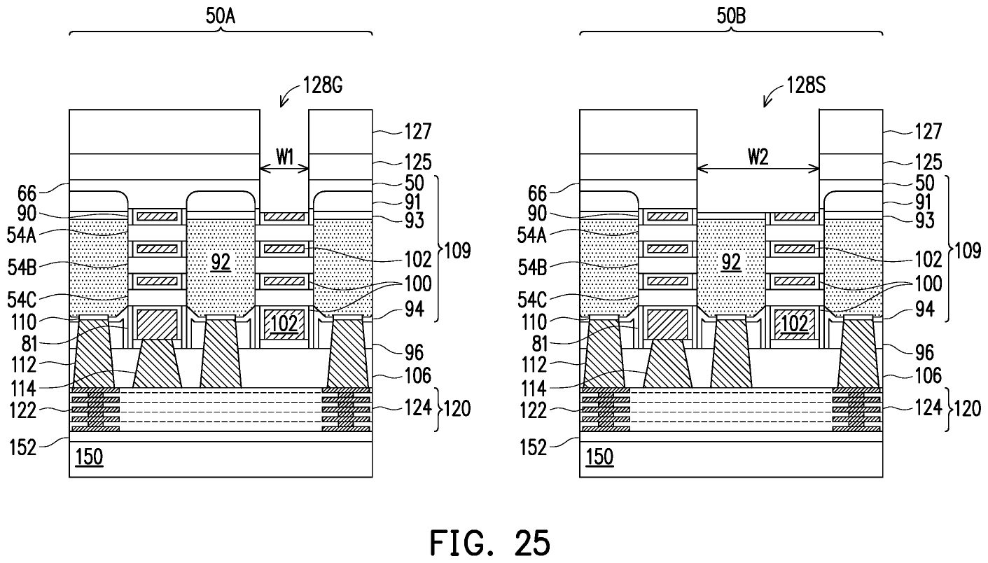

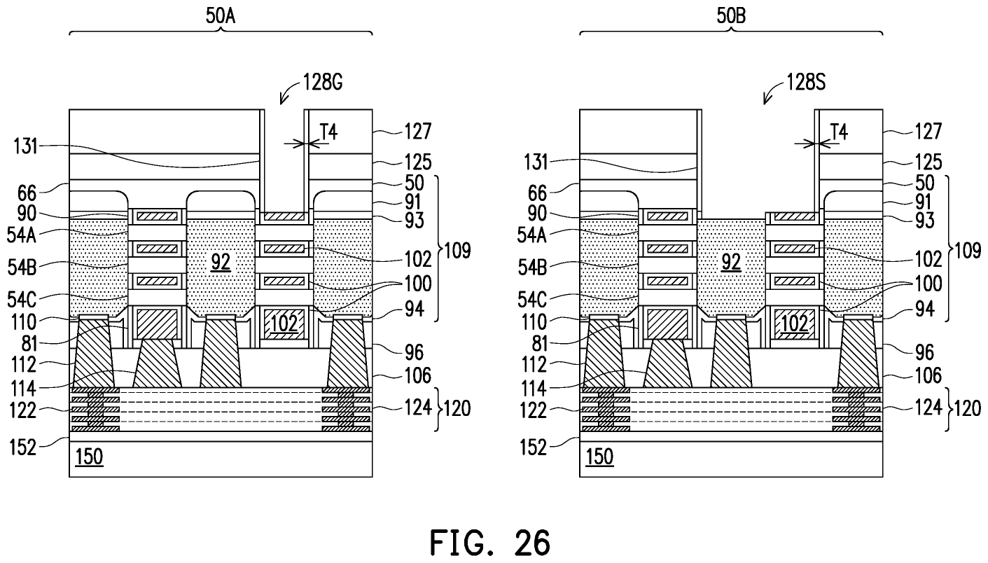

In FIG. 25, an opening 128G and an opening 128S are formed through the first back-side dielectric layer 125, the second back-side dielectric layer 127, and the substrate 50 in the region 50A and in the region 50B, respectively. The opening 128G may expose a back-side surface of a gate electrode 102, such as a gate electrode 102 that is not connected to a gate contact 114 on the front-side of the transistor structure 109 in the region 50A. The opening 128S may expose a back-side surface of a gate electrode 102, such as a gate electrode 102 that is not connected to a gate contact 114 on the front-side of the transistor structure 109. The opening 128S may also expose a back-side surface of the bottom spacer 93 adjacent the gate electrode 102 exposed by the opening 128S. The opening 128G and the opening 128S may be formed simultaneously by a series of etching steps. For example, a first etching step may be used to remove portions of the first back-side dielectric layer 125 and the second back-side dielectric layer 127. The first etching step may be a dry etching process utilizing etchants such as fluoromethane, tetrafluoromethane, hydrogen, combinations thereof, or the like. Then a second etching step may be used to remove portions of the substrate 50 and the semiconductor layer 91. The second etching step may be a dry etching process utilizing etchants such as chlorine, hydrobromic acid, oxygen, combinations thereof, or the like. Then a third etching step may be used to remove portions of the gate dielectric layers 100. The third etching step may be a wet etching process utilizing etchants such as hydrofluoric acid or the like. The opening 128G may have a width W1 in a range of about 10 nm to about 20 nm. The opening 128S may have a width W2 in a range of about 30 nm to about 50 nm. The width W2 may be greater than the width W1.

In FIG. 26, contact spacers 131 are formed on sidewalls of the opening 128G and the opening 128S in the region 50A and in the region 50B, respectively. Further, the portions of the bottom spacers 93 exposed by the opening 128S are removed in the region 50B. The contact spacers 131 may be formed of a dielectric material, such as silicon nitride or the like, and formed by a deposition process, such as CVD, ALD, or the like. Initially, the material of the contact spacers 131 may also form on bottom surfaces of the opening 128G and the opening 128S, which may be then removed by an etching step. The etching step may be a dry etching process utilizing etchants such as fluoromethane, difluoromethane, nitrogen, hydrogen, combinations thereof, or the like. In the region 50B, the etching step may also remove the bottom spacer 93 exposed by the opening 128S to expose a back-side surface of the underlying epitaxial source/drain region 92. The dry etching process may selectively etch the material(s) of the contact spacers 131 and the bottom spacer 93 at a faster rate than the materials of the gate electrode 102 and the epitaxial source/drain region 92. For example, the bottom spacers 93 and the contact spacers 131 may be formed of the same dielectric material, and the etching may be selective to that dielectric material. As such, the contact spacers 131 and the bottom spacer 93 may be removed without significantly removing the materials of the gate electrode 102 and the epitaxial source/drain region 92. In some embodiments, the dry etching process is an anisotropic etching process, and a portion of the bottom spacer 93 directly underneath the portion of the contact spacers 131 on the sidewall of the opening 128S remains after the dry etching process, as a result of being masked by the contact spacers 131 during the etching. As a result, the bottom spacer 93 may be partially removed by the dry etching process. The contact spacers 131 may have thickness T4 in a range of about 2 nm to about 5 nm.

In FIG. 27, a second silicide region 129 is formed over the exposed epitaxial source/drain region 92 in the region 50B. In some embodiments, the exposed back-side surface of the epitaxial source/drain region 92 is completely covered by the second silicide region 129. The second silicide region 129 may be formed of a same or similar material and by a same or similar process as the first silicide regions 110, described above with respect to FIGS. 19A through 19C. A second thermal annealing process may be used to form the second silicide region 129. The second thermal annealing process may be performed at temperature that is lower than the temperature of the first thermal annealing process used to form the first silicide regions 110. In some embodiments, the second thermal annealing process is performed at a temperate of about 400° C. As a result, diffusion of the material in first conductive features 122 of the front-side interconnect structure 120 may be reduced during the second thermal annealing process. The second silicide region 129 may have thickness T5 in a range of about 5 nm to about 10 nm. The thickness T5 of the second silicide region 129 may be different from a thickness of the first silicide regions 110.

In FIG. 28, gate contact 130G is formed in the opening 128G in the region 50A and shared contact 130S is formed in the opening 128S in the region 50B. The gate contact 130G and the shared contact 130S may be also referred to as conductive contacts. The gate contact 130G may be electrically connected to and in contact with an underlying gate electrode 102. The shared contact 130S may be electrically connected to and in contact with a gate electrode 102 and with an epitaxial source/drain region 92 (via the second silicide region 129). The gate contact 130G and the shared contact 130S may each comprise a barrier layer (not shown). The gate contact 130G and the shared contact 130S may each further comprise a conductive material, such as tungsten, cobalt, ruthenium, a combination of titanium, titanium nitride, and tungsten, or the like. The material of the gate contact 130G and the shared contact 130S may be formed by a deposition process, a plating process, or the like. Then a planarization process, such as CMP, may be performed to remove excess conductive material and the second back-side dielectric layer 127. The first back-side dielectric layer 125 may be used as a CMP stop layer during the planarization process. After the planarization process, surfaces of the gate contact 130G, the shared contact 130S, the contact spacers 131, and the first back-side dielectric layer 125 may be substantially co-planar (within process variations) with one another. The gate contact 130G may have a width W3 in a range of about 4 nm to about 16 nm. In some embodiments, the width W3 is similar to a width of the underlying gate electrode 102. The shared contact 130S may have a width W4 in a range of about 24 nm to about 46 nm. The width W4 may be greater than the width W3. A first bottom surface of the shared contact 130S in contact with the gate electrode 102 may be spaced apart from a second bottom surface of the shared contact 130S in contact with the second silicide region 129 by a distance D1. The distance D1 may be smaller than about 10 nm. As a result, voids in the shared contact 130S may be reduced or prevented during the deposition process, thereby improving the long-term reliability of the semiconductor die.

In FIG. 29A, a back-side interconnect structure 136 is formed on the first back-side dielectric layer 125 and the gate contact 130G in the region 50A as well as on the first back-side dielectric layer 125 and the shared contact 130S in the region 50B. The back-side interconnect structure 136 may be referred to as a back-side interconnect structure because it is formed on a back-side of the device layer in which transistor structures 109 are disposed (e.g., a side of the transistor structures 109 opposite the gate electrodes 102). In particular, the back-side interconnect structure 136 may comprise stacked layers of second conductive features 140 formed in second dielectric layers 138. The second conductive features 140 may be electrically connected to the gate contact 130G and the shared contact 130S. The second conductive features 140 may include conductive lines and conductive vias. A first layer of the conductive lines may be in contact with the gate contact 130G and the shared contact 130S. The second dielectric layers 138 may be formed of the same or similar materials using the same or similar processes as the first dielectric layers 124, and the second conductive features 140 may be formed of the same or similar materials using the same or similar processes as the first conductive features 122.

A passivation layer 144, under bump metallizations (UBMs) 146, and external connectors 148 are formed over the back-side interconnect structure 136. The passivation layer 144 may comprise polymers such as PBO, polyimide, BCB, or the like. Alternatively, the passivation layer 144 may include non-organic dielectric materials such as silicon oxide, silicon nitride, silicon carbide, silicon oxynitride, or the like. The passivation layer 144 may be deposited by, for example, CVD, PVD, ALD, or the like. The UBMs 146 are formed through the passivation layer 144 to the second conductive features 140 of the back-side interconnect structure 136. The UBMs 146 may comprise one or more layers of copper, nickel, gold, or the like, which are formed by a plating process, or the like. The external connectors 148 (e.g., solder balls) are formed on the UBMs 146. The formation of the external connectors 148 may include placing solder balls on exposed portions of the UBMs 146 and reflowing the solder balls. In some embodiments, the formation of the external connectors 148 includes performing a plating step to form solder regions over the topmost conductive lines and then reflowing the solder regions. The UBMs 146 and the external connectors 148 may be used to provide input/output connections to other electrical components, such as, other device dies, redistribution structures, printed circuit boards (PCBs), motherboards, or the like. The UBMs 146 and the external connectors 148 may also be referred to as back-side input/output pads that may provide signal, supply voltage, and/or ground connections to the nano-FETs described above.

Subsequently, a singulation process may be applied along scribe lines to separate individual semiconductor dies 200 on the carrier substrate 150 from each other. In this manner, a semiconductor die 200 having a front-side interconnect structure 120, a device layer comprising transistor structures 109, and a back-side interconnect structure 136 may be manufactured. The region 50A and the region 50B may be different regions on a same semiconductor die 200 or on different semiconductor dies 200.

FIG. 29B shows top-down views (e.g., layout views) of the region 50A and the region 50B. Various features in the region 50A and the region 50B are omitted in FIG. 29B for illustrative purposes. In the region 50A, the gate contact 130G may be between adjacent epitaxial source/drain regions 92. The gate contact 130G may have a width W5 along a longitudinal direction of the gate electrode 102 and the epitaxial source/drain regions 92 may have width W6 along the longitudinal direction of the gate electrode 102. In some embodiments, the width W5 is smaller than the width W6. In the region 50B, the shared contact 130S may have a width W7 along a longitudinal direction of the gate electrode 102 and the epitaxial source/drain regions 92 may have width W8 along the longitudinal direction of the gate electrode 102. In some embodiments, the width W7 is smaller than the width W8. The shared contact 130S may be aligned with the underlying fin 66 in the top-down view. The gate contact 130G may be aligned with the underlying fin 66 in the top-down view.

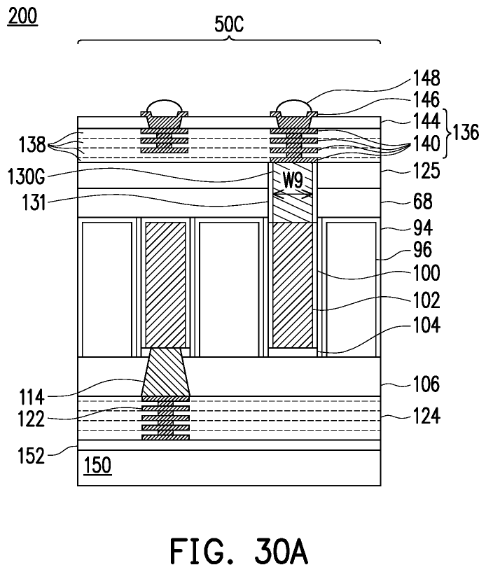

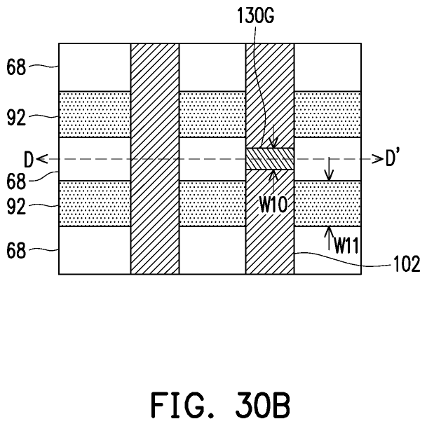

FIGS. 30A and 30B are views of a semiconductor die including nano-FETs, in accordance with some other embodiments. FIG. 30A illustrates a cross-sectional view along reference cross-section D-D′ illustrated in FIG. 1. FIG. 30B is a top-down view, where the regions of FIG. 30A are shown along reference cross-section D-D′ in FIG. 30B.

FIG. 30A shows a region 50C of the semiconductor die 200, which is along reference cross-section D-D′ as shown in FIG. 1. The region 50C of FIGS. 30A-30B may be formed on a same semiconductor die 200 as the regions 50A and 50B of FIG. 29A-29B, wherein like numerals refer to like features. In the embodiments where the region 50A, the region 50B, and the region C are on the same semiconductor die 200, the region 50A, the region 50B, and the region C may be across a same gate electrode 102 or different gate electrodes 102. In the region 50C, the gate contact 130G extends through the first back-side dielectric layer 125 and the STI region 68 to be electrically connected to the gate electrode 102. The gate contact 130G in the region 50C may be formed of the same or similar materials using the same or similar processes as the gate contact 130G in the region 50A. In the embodiments where the region 50A and the region 50C are on the same semiconductor die 200, the gate contacts 130G in the region 50A and the region 50C may be formed simultaneously. The gate contact 130G in the region 50C may have a width W9 in a range of about 4 nm to about 16 nm. In some embodiments, the width W9 is similar to a width of the underlying gate electrode 102.

FIG. 30B shows a top-down view (e.g., layout views) of the region 50C. Various features in the region 50C are omitted in FIG. 30B for illustrative purposes. The gate contact 130G may be aligned with the underlying STI region 68 in the top-down view. The gate contact 130G may have a width W10 along a longitudinal direction of the gate electrode 102 and the epitaxial source/drain regions 92 may have width W11 along the longitudinal direction of the gate electrode 102. In some embodiments, the width W10 is smaller than the width W11.

The embodiments of the present disclosure have some advantageous features. By forming the gate contact 130G and the shared contact 130S on back-sides of the transistor structures 109, the density of the conductive contacts, including the source/drain contacts 112 and the gate contacts 114, on the front-sides of the transistor structures 109 may be reduced, which may reduce shorting and parasitic capacitance between adjacent conductive contacts on the front-sides of the transistor structures 109. Further, voids in the shared contact 130S may be reduced or prevented. As a result, the performance and the long-term reliability of the semiconductor dies 200 may be improved.

In an embodiment, a device includes a first interconnect structure; a second interconnect structure including a conductive feature; and a device layer between the first interconnect structure and the second interconnect structure, the device layer including: a semiconductor fin; a first gate structure on the semiconductor fin; a source/drain region adjacent the first gate structure; and a shared contact extending through the semiconductor fin to be electrically connected to the source/drain region and the first gate structure, the conductive feature contacting the shared contact. In an embodiment, the device layer further includes a second gate structure on the semiconductor fin; and a gate contact extending through the semiconductor fin to be electrically connected to the second gate structure. In an embodiment, the device layer further includes an isolation region adjacent the semiconductor fin; a second gate structure on the isolation region and the semiconductor fin; and a gate contact extending through the isolation region to be electrically connected to the second gate structure. In an embodiment, the device layer further includes a contact spacer between the shared contact and the semiconductor fin. In an embodiment, the device further includes a silicide region between the shared contact and the source/drain region. In an embodiment, a first bottom surface of the shared contact is in contact with the silicide region, a second bottom surface of the shared contact is in contact with the first gate structure, and the first bottom surface is spaced apart from the second bottom surface. In an embodiment, the device further includes a dielectric layer between the semiconductor fin and the second interconnect structure, wherein the shared contact extends through the dielectric layer.

In an embodiment, a device includes a first gate electrode; a second gate electrode; a source/drain region beside the first gate electrode; and a semiconductor fin on the source/drain region, the first gate electrode, and the second gate electrode; a shared contact extending through the semiconductor fin and connected to a back-side of the first gate electrode and a back-side of the source/drain region; a first gate contact extending through the semiconductor fin and connected to a back-side of the second gate electrode; and a first interconnect structure on the first gate contact and the shared contact, wherein the first interconnect structure includes first conductive features, the first conductive features being electrically connected to the shared contact and the first gate contact. In an embodiment, the device further includes a contact spacer separating the shared contact and the semiconductor fin. In an embodiment, the device further includes an interlayer dielectric on a front-side of the source/drain region; a source/drain contact extending through the interlayer dielectric and connected to the front-side of the source/drain region; and a second interconnect structure on the source/drain contact, wherein the second interconnect structure includes second conductive features, the second conductive features being electrically connected to the source/drain contact. In an embodiment, the device further includes a third gate electrode; an isolation region adjacent the semiconductor fin and on the third gate electrode; and a second gate contact extending through the isolation region and connected to the third gate electrode. In an embodiment, the first gate contact has a smaller width than the source/drain region in a longitudinal direction of the first gate electrode in a top-down view.

In an embodiment, a method includes forming a first interconnect structure over a front-side of a first gate electrode, a front-side of a second gate electrode, and a front-side of a source/drain region, the source/drain region disposed adjacent the first gate electrode, the first gate electrode and the second gate electrode disposed on a semiconductor fin, the semiconductor fin protruding from an isolation region; forming a first dielectric layer on the semiconductor fin and the isolation region; forming a first opening through the first dielectric layer and the semiconductor fin, the first opening exposing a back-side of the first gate electrode and a back-side of the source/drain region; forming a shared contact in the first opening; and forming a second interconnect structure over the first dielectric layer, the second interconnect structure including a conductive feature, the conductive feature connected to the shared contact. In an embodiment, the method further includes forming a second opening through the first dielectric layer and the semiconductor fin, the second opening exposing a back-side of the second gate electrode, and forming a gate contact in the second opening. In an embodiment, the method further includes forming a second opening through the first dielectric layer and the isolation region, the second opening exposing a back-side of the second gate electrode, and forming a gate contact in the second opening. In an embodiment, a second dielectric layer between the semiconductor fin and the source/drain region is at least partially removed after forming the first opening. In an embodiment, the method further includes forming a silicide region in the first opening and the source/drain region before forming the shared contact. In an embodiment, the shared contact is narrower than the source/drain region along a longitudinal direction of the first gate electrode in a top-down view. In an embodiment, the method further includes forming contact spacers along sidewalls of the first opening before forming the shared contact. In an embodiment, the method further includes removing a second dielectric layer on the back-side of the first gate electrode during forming the first opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first interconnect structure;
a second interconnect structure comprising a conductive feature; and
a device layer between the first interconnect structure and the second interconnect structure, the device layer comprising:
a semiconductor fin;
a first gate structure on the semiconductor fin;
a source/drain region adjacent the first gate structure; and
a shared contact extending through the semiconductor fin to be electrically connected to the source/drain region and the first gate structure, the conductive feature contacting the shared contact.

2. The device of claim 1, wherein the device layer further comprises:
a second gate structure on the semiconductor fin; and
a gate contact extending through the semiconductor fin to be electrically connected to the second gate structure.

3. The device of claim 1, wherein the device layer further comprises:
an isolation region adjacent the semiconductor fin;
a second gate structure on the isolation region and the semiconductor fin; and
a gate contact extending through the isolation region to be electrically connected to the second gate structure.

4. The device of claim 1, wherein the device layer further comprises:
a contact spacer between the shared contact and the semiconductor fin.

5. The device of claim 1, further comprising:
a silicide region between the shared contact and the source/drain region.

6. The device of claim 5, wherein a first bottom surface of the shared contact is in contact with the silicide region, a second bottom surface of the shared contact is in contact with the first gate structure, and the first bottom surface is spaced apart from the second bottom surface.

7. The device of claim 1, further comprising:
a dielectric layer between the semiconductor fin and the second interconnect structure, wherein the shared contact extends through the dielectric layer.

8. A device comprising:
a first gate electrode;
a second gate electrode;
a source/drain region beside the first gate electrode; and
a semiconductor fin on the source/drain region, the first gate electrode, and the second gate electrode;
a shared contact extending through the semiconductor fin and connected to a back-side of the first gate electrode and a back-side of the source/drain region;
a first gate contact extending through the semiconductor fin and connected to a back-side of the second gate electrode; and
a first interconnect structure on the first gate contact and the shared contact, wherein the first interconnect structure comprises first conductive features, the first conductive features being electrically connected to the shared contact and the first gate contact.

9. The device of claim 8, further comprising:
a contact spacer separating the shared contact and the semiconductor fin.

10. The device of claim 8, further comprising:
an interlayer dielectric on a front-side of the source/drain region;
a source/drain contact extending through the interlayer dielectric and connected to the front-side of the source/drain region; and
a second interconnect structure on the source/drain contact, wherein the second interconnect structure comprises second conductive features, the second conductive features being electrically connected to the source/drain contact.

11. The device of claim 8, further comprising:
a third gate electrode;
an isolation region adjacent the semiconductor fin and on the third gate electrode; and
a second gate contact extending through the isolation region and connected to the third gate electrode.

12. The device of claim 8, wherein the first gate contact has a smaller width than the source/drain region in a longitudinal direction of the first gate electrode in a top-down view.

13. A method comprising:
forming a first interconnect structure over a front-side of a first gate electrode, a front-side of a second gate electrode, and a front-side of a source/drain region, the source/drain region disposed adjacent the first gate electrode, the first gate electrode and the second gate electrode disposed on a semiconductor fin, the semiconductor fin protruding from an isolation region;
forming a first dielectric layer on the semiconductor fin and the isolation region;
forming a first opening through the first dielectric layer and the semiconductor fin, the first opening exposing a back-side of the first gate electrode and a back-side of the source/drain region;
forming a shared contact in the first opening; and
forming a second interconnect structure over the first dielectric layer, the second interconnect structure comprising a conductive feature, the conductive feature connected to the shared contact.

14. The method of claim 13, further comprising:
forming a second opening through the first dielectric layer and the semiconductor fin, the second opening exposing a back-side of the second gate electrode, and
forming a gate contact in the second opening.

15. The method of claim 13, further comprising:
forming a second opening through the first dielectric layer and the isolation region, the second opening exposing a back-side of the second gate electrode, and
forming a gate contact in the second opening.

16. The method of claim 13, wherein a second dielectric layer between the semiconductor fin and the source/drain region is at least partially removed after forming the first opening.

17. The method of claim 13, further comprising:
forming a silicide region in the first opening and the source/drain region before forming the shared contact.

18. The method of claim 13, wherein the shared contact is narrower than the source/drain region along a longitudinal direction of the first gate electrode in a top-down view.

19. The method of claim 13, further comprising:
forming contact spacers along sidewalls of the first opening before forming the shared contact.

20. The method of claim 13, further comprising:
removing a second dielectric layer on the back-side of the first gate electrode during forming the first opening.
